(19) United States
(12) Patent Application Publication
(10) Pub. No.: US 2011/0103167 A1
(43) Pub. Date: May 5, 2011

(54) SENSE AMPLIFIER AND SEMICONDUCTOR MEMORY APPARATUS INCLUDING THE SAME

(75) Inventors: Kyeong Pil KANG, Ichon-shi (KR); Jong Chern LEE, Ichon-shi (KR)

(73) Assignee: Hynix Semiconductor Inc., Ichon-shi (KR)

(21) Appl. No.: 12/839,345

(22) Filed: Jul. 19, 2010

(30) Foreign Application Priority Data
Oct. 30, 2009 (KR) 10-2009-0103938

(51) Int. Cl. G11C 7/06

(52) U.S. Cl. 365/207; 365/205

(57) ABSTRACT

A local sense amplifier of a semiconductor memory apparatus includes a read amplification unit configured to amplify data of first data lines and transfer the amplified data to second data lines during a read operation; and a write amplification unit configured to amplify data of the second data lines and transfer the amplified data to the first data lines during a write operation.

### CROSS-REFERENCES TO RELATED APPLICATION

The present application claims priority under 35 U.S.C. §119(a) to Korean Application No. 10-2009-0103938, filed on Oct. 30, 2009, in the Korean Intellectual Property Office, which is incorporated herein by reference in its entirety as if set forth in full.

### BACKGROUND

1. Technical Field

The present invention relates to a semiconductor integrated circuit, and more particularly, to a local sense amplifier of a semiconductor memory apparatus.

2. Related Art

A semiconductor memory apparatus typically amplifies the data of a memory cell to transfer them to first data lines, and subsequently amplifies the transferred data of the first data lines to transfer them to second data lines. Division of data lines and amplification of the data of each divided data lines increase loading speeds of the data lines and provide precise transfer of the data.

Generally, a circuit that is coupled between the first and second data lines and amplifies the data of the data lines is called a local sense amplifier.

Referring to FIG. 1, a conventional local sense amplifier 10 of a semiconductor memory apparatus includes first to seventh transistors N1-N7. If a read signal RD is enabled, the local sense amplifier 10 amplifies the data of first data lines SIO and SIOB and transfers the amplified data to second data lines LIO and LIOB. If a write signal WT is enabled, the local sense amplifier 10 transfers the data of the second data lines LIO and LIOB to the first data lines SIO and SIOB. The first data lines SIO and SIOB are disposed closer to a data storage region than the second data lines LIO and LIOB.

The local sense amplifier 10 includes the transistors N6 and N7 that connect the first data lines SIO and SIOB and the second data lines LIO and LIOB when the write signal WT is enabled.

Therefore, during a write operation, a pumping voltage (a high potential voltage) should be applied to the gates of the transistors N6 and N7, that is, the write signal WT should be enabled at the level of the pumping voltage, for avoiding the loss of data when transferring the data of the second data lines LIO and LIOB to the first data lines SIO and SIOB. Also, it is necessary to increase the size of the transistors N6 and N7 for completely, electrically disconnecting the first data lines SIO and SIOB from the second data lines LIO and LIOB during a read operation.

### SUMMARY

Accordingly, various exemplary embodiments of the invention may provide a local sense amplifier of a semiconductor memory apparatus in which transistors for controlling connection between data lines are removed.

In one embodiment of the present invention, there is provided a semiconductor memory apparatus including a sense amplifier. The sense amplifier in the semiconductor memory apparatus comprises a read amplification unit configured to amplify data of first data lines to transfer the amplified data to second data lines during a read operation; and a write amplification unit configured to amplify data of the second data lines to transfer the amplified data to the first data lines during a write operation.

In another embodiment of the present invention, there is provided a sense amplifier comprising: a first pair of data lines comprising a first data line and a first data bar line; and a second pair of data lines comprising a second data line and a second data bar line. During a read operation, a voltage level of the second data bar line is lowered as a voltage level of the first data line is high, and a voltage level of the second data line is lowered as a voltage level of the first data bar line is high. Furthermore, during a write operation, the voltage level of the first data bar line is lowered as the voltage level of the second data line is high, and the voltage level of the first data line is lowered as the voltage level of the second data bar line is high.

In another embodiment of the present invention, a sense amplifier of a semiconductor memory. apparatus comprises a first transistor and a second transistor. A first data line is coupled to a gate of the first transistor and a drain of the second transistor, and a second data line is coupled to a gate of the second transistor and a drain of the first transistor. Furthermore, a source of the first transistor is connected to a ground terminal during a read operation, and a source of the second transistor is connected to the ground terminal during a write operation.

### BRIEF DESCRIPTION OF THE DRAWINGS

Features, aspects, and embodiments are described in conjunction with the attached drawings, in which:

FIG. 1 is a diagram illustrating a configuration of a conventional local sense amplifier of a semiconductor memory apparatus; and

FIG. 2 is a diagram schematically illustrating a configuration of a local sense amplifier of a semiconductor memory apparatus in accordance with an embodiment of the present invention.

### DETAILED DESCRIPTION

Reference will now be made in detail to the exemplary embodiments consistent with the present disclosure, examples of which are illustrated in the accompanying drawings. Whenever possible, the same reference numerals will be used throughout the drawings to refer to the same or like parts.

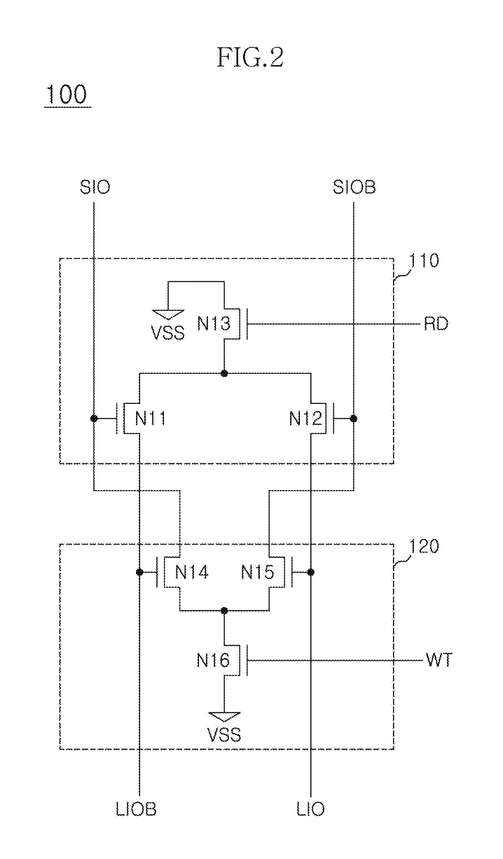

Referring to FIG. 2, a local sense amplifier 100 of a semiconductor memory apparatus in accordance with an embodiment of the present invention may include a read amplification unit 110 and a write amplification unit 120.

The read amplification unit 110 is configured to amplify the data of first data lines SIO and SIOB and transfer the amplified data to second data lines LIO and LIOB. The first data lines SIO and SIOB may be disposed closer to a data storage region than the second data lines LIO and LIOB.

Hereafter, in order to distinguish the pair of first data lines SIO and SIOB shown in the drawing, the pair of first data lines SIO and SIOB are respectively designated as a first data line SIO and a first data bar line SIOB. Also, in order to distinguish the pair of second data lines LIO and LIOB, the pair of second data lines LIO and LIOB are respectively designated as a second data line LIO and a second data bar line LIOB.

During a read operation, the read amplification unit 110 determines the voltage levels of the second data line LIO and the second data bar line LIOB in response to the voltage levels of the first data line SIO and the first data bar line SIOB.

When a read signal RD is enabled, the read amplification unit 110 compares the voltage levels of the first data line SIO and the first data bar line SIOB, and lowers the voltage level of one of the second data line LIO and the second data bar line LIOB. For example, if the read signal RD is enabled and the voltage level of the first data line SIO is higher than the voltage level of the first data bar line SIOB, the read amplification unit 110 lowers the voltage level of the second data bar line LIOB below the voltage level of the second data line LIO. If the read signal RD is enabled and the voltage level of the first data bar line SIOB is higher than the voltage level of the first data line SIO, the read amplification unit 110 lowers the voltage level of the second data line LIO below the voltage level of the second data bar line LIOB.

The read amplification unit 110 may include first to third transistors N11-N13. The first transistor N11 has a gate coupled to the first data line SIO and a drain coupled to the second data bar line LIOB. The second transistor N12 has a gate coupled to the first data bar line SIOB and a drain coupled to the second data line LIO. The third transistor N13 has a gate through which the read signal RD is received, a drain coupled to the sources of the first transistor N11 and the second transistor N12, and a source coupled to a ground terminal VSS.

During a write operation, the write amplification unit 120 determines the voltage levels of the first data line SIO and the first data bar line SIOB in response to the voltage levels of the second data line LIO and the second data bar line LIOB.

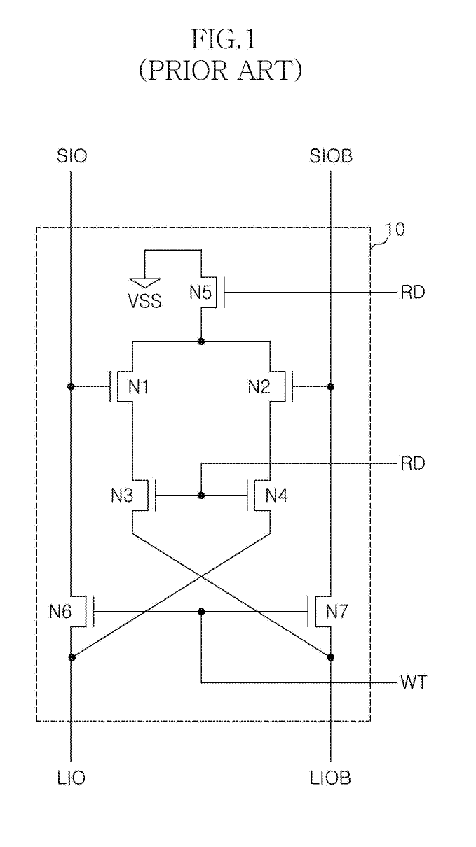

When a write signal WT is enabled, the write amplification unit 120 compares the voltage levels of the second data line LIO and the second data bar line. LIOB, and lowers the voltage level of one of the first data line SIO and the first data bar line SIOB. For example, if the write signal WT is enabled and the voltage level of the second data line LIO is higher than the voltage level of the second data bar line LIOB, the write amplification unit 120 lowers the voltage level of the first data bar line SIOB below the voltage level of the first data line SIO. If the write signal WT is enabled and the voltage level of the second data bar line LIOB is higher than the voltage level of the second data line LIO, the write amplification unit 120 lowers the voltage level of the first data line SIO below the voltage level of the first data bar line SIOB. In the conventional art (see FIG. 1), the conventional local sense amplifier 10 includes the components N6 and N7 that electrically couple the first data lines SIO and SIOB with the second data lines. LIO and LIOB during the write operation. Conversely, the local sense amplifier 100 in accordance with the embodiment of the present invention does not include any components for electrically coupling the first data line SIO and SIOB with the second data lines LIO and LIOB during the write operation.

The write amplification unit 120 may include fourth to sixth transistors N14-N16. The fourth transistor N14 has a gate coupled to the second data bar line LIOB and a drain coupled to the first data line SIO. The fifth transistor N15 has a gate coupled to the second data line LIO and a drain coupled to the first data bar line SIOB. The sixth transistor N16 has a gate to which the write signal WT is inputted, a drain coupled to the sources of the fourth transistor N14 and the fifth transistor N15, and a source coupled to the ground terminal VSS.

The local sense amplifier 100 of a semiconductor memory apparatus in accordance with the embodiment of the present invention, configured as mentioned above, may operate as described below.

The read amplification unit 110 lowers the voltage level of the second data bar line LIOB below the voltage level of the second data line LIO when the read signal RD is enabled and the voltage level of the first data line SIO is higher than the voltage level of the first data bar line SIOB. The read amplification unit 110 lowers the voltage level of the second data line LIO below the voltage level of the second data bar line LIOB when the read signal RD is enabled and the voltage level of the first data bar line SIOB is higher than the voltage level of the first data line SIO.

The write amplification unit 120 lowers the voltage level of the first data bar line SIOB below the voltage level of the first data line SIO when the write signal WT is enabled and the voltage level of the second data line LIO is higher than the voltage level of the second data bar line LIOB. The write amplification unit 120 lowers the voltage level of the first data line SIO below the voltage level of the first data bar line SIOB when the write signal WT is enabled and the voltage level of the second data bar line LIOB is higher than the voltage level of the second data line LIO.

The local sense amplifier 100 of a semiconductor memory apparatus in accordance with the embodiment of the present invention amplifies the data of the first data lines SIO and SIOB and transfers the amplified data to the second data lines LIO and LIOB during the read operation, and amplifies the data of the second data lines LIO and LIOB and transfers the amplified data to the first data lines SIO and SIOB during the write operation.

The local sense amplifier 100 in accordance with the embodiment of the present invention, unlike the conventional art (see FIG. 1), does not include the switches N6 and N7 for electrically connecting the first data lines SIO and SIOB to the second data lines LIO and LIOB. Therefore, according to the present invention, a local sense amplifier may consist of smaller transistors than the conventional art, thereby improving spatial efficiency. Also, since a pumping voltage for driving the switches N6 and N7 are not used, the degradation of the local sense amplifier may be substantially prevented.

While a certain embodiment has been described above with reference to illustrative examples for particular applications, it will be understood to those skilled in the art that the embodiment described is by way of example only. Those skilled in the art with access to the teachings provided in this disclosure will recognize additional modifications, applications, and/or embodiments and additional fields in which the present disclosure would be of significant utility. Accordingly, the local sense amplifier of a semiconductor memory apparatus described herein should not be limited based on the described embodiment. Rather, the local sense amplifier of a semiconductor memory apparatus described herein should only be limited in light of the claims that follow when taken in conjunction with the above description and accompanying drawings.

What is claimed is:

1. A semiconductor memory apparatus including a sense amplifier, the sense amplifier comprising:
a read amplification unit configured to amplify data of first data lines to transfer the amplified data to second data lines during a read operation; and
a write amplification unit configured to amplify data of the second data lines to transfer the amplified data to the first data lines during a write operation.

2. The semiconductor memory apparatus according to claim 1, wherein the first data lines are located closer to a data storage region than the second data lines.

3. The semiconductor memory apparatus according to claim 1,
wherein the first data lines comprise a first data line and a first data bar line,
wherein the second data lines comprise a second data line and a second data bar line, and
wherein the read amplification unit is configured to receive a read signal, and to compare a voltage level of the first data line with a voltage level of the first data bar line and lower one of the voltage levels of the second data line and the second data bar line when the read signal is enabled.

4. The semiconductor memory apparatus according to claim 3, wherein the read amplification unit is configured to lower the voltage level of the second data bar line below the voltage level of the second data line when the read signal is enabled and the voltage level of the first data line is higher than the voltage level of the first data bar line.

5. The semiconductor memory apparatus according to claim 4, wherein the read amplification unit is configured to lower the voltage level of the second data line below the voltage level of the second data bar line when the read signal is enabled and the voltage level of the first data bar line is higher than the voltage level of the first data line.

6. The semiconductor memory apparatus according to claim 5, wherein the read amplification unit comprises:
a first transistor having a gate coupled to the first data line and a drain coupled to the second data bar line;
a second transistor having a gate coupled to the first data bar line and a drain coupled to the second data line; and
a third transistor having a gate through which the read signal is received, a drain coupled to sources of the first transistor and the second transistor, and a source coupled to a ground terminal.

7. The semiconductor memory apparatus according to claim 1,
wherein the first data lines comprise a first data line and a first data bar line,
wherein the second data lines comprise a second data line and a second data bar line, and
wherein the write amplification unit is configured to receive a write signal, and to compare a voltage level of the second data line with a voltage level of the second data bar line and lower one of the voltage levels of the first data line and the first data bar line when the write signal is enabled.

8. The semiconductor memory apparatus according to claim 7, wherein the write amplification unit is configured to lower the voltage level of the first data bar line below the voltage level of the first data line when the write signal is enabled and the voltage level of the second data line is higher than the voltage level of the second data bar line.

9. The semiconductor memory apparatus according to claim 8, wherein the write amplification unit is configured to lower the voltage level of the first data line below the voltage level of the first data bar line when the write signal is enabled and the voltage level of the second data bar line is higher than the voltage level of the second data line.

10. The semiconductor memory apparatus according to claim 9, wherein the write amplification unit comprises:
a fourth transistor having a gate coupled to the second data line and a drain coupled to the first data bar line;
a fifth transistor having a gate coupled to the second data bar line and a drain coupled to the first data line; and
a sixth transistor having a gate through which the write signal is received, a drain coupled to sources of the fourth transistor and the fifth transistor, and a source coupled to a ground terminal.

11. A sense amplifier comprising:
a first pair of data lines comprising a first data line and a first data bar line; and
a second pair of data lines comprising a second data line and a second data bar line;
wherein, during a read operation, a voltage level of the second data bar line is lowered as a voltage level of the first data line is high, and a voltage level of the second data line is lowered as a voltage level of the first data bar line is high, and
wherein, during a write operation, the voltage level of the first data bar line is lowered as the voltage level of the second data line is high, and the voltage level of the first data line is lowered as the voltage level of the second data bar line is high.

12. The sense amplifier according to claim 11, wherein the first data line and the first data bar line are located closer to a data storage region than the second data line and the second data bar line.

13. The sense amplifier according to claim 11, further comprising:
a read amplification unit configured to determine the voltage level of the second data line and the voltage level of the second data bar line in response to the voltage level of the first data line and the voltage level of the first data bar line during the read operation; and
a write amplification unit configured to determine the voltage level of the first data line and the voltage level of the first data bar line in response to the voltage level of the second data line and the voltage level of the second data bar line during the write operation.

14. The sense amplifier according to claim 13, wherein the read amplification unit comprises:
a first transistor having a gate coupled to the first data line and a drain coupled to the second data bar line;
a second transistor having a gate coupled to the first data bar line and a drain coupled to the second data line; and
a third transistor having a gate through which the read signal is received, a drain coupled to sources of the first transistor and the second transistor, and a source coupled to a ground terminal.

15. The sense amplifier according to claim 13, wherein the write amplification unit comprises:
a fourth transistor having a gate coupled to the second data line and a drain coupled to the first data bar line;
a fifth transistor having a gate coupled to the second data bar line and a drain coupled to the first data line; and
a sixth transistor having a gate through which the write signal is received, a drain coupled to sources of the fourth transistor and the fifth transistor, and a source coupled to a ground terminal.

16. A sense amplifier of a semiconductor memory apparatus comprising a first transistor and a second transistor,
wherein a first data line is coupled to a gate of the first transistor and a drain of the second transistor,
wherein a second data line is coupled to a gate of the second transistor and a drain of the first transistor, and
wherein a source of the first transistor is connected to a ground terminal during a read operation, and a source of the second transistor is connected to the ground terminal during a write operation.

17. The sense amplifier according to claim 16,
wherein the first data line is configured to transfer data to the second data line during the read operation, and
wherein the second data line is configured to transfer data to the first data line during the write operation.

18. The sense amplifier according to claim 17, further comprising:
a third transistor having a gate through which a read signal is received, a source coupled to the ground terminal, and a drain coupled to the source of the first transistor; and
a fourth transistor having a gate through which a write signal is received, a source coupled to the ground terminal, and a drain coupled to the source of the second transistor.
